(19) United States
(12) Patent Application Publication
(10) Pub. No.: US 2020/0113085 A1
(43) Pub. Date: Apr. 9, 2020

(54) SYSTEM AND METHOD FOR RECOVERING AND UPGRADING WASTE HEAT WHILE COOLING DEVICES

(71) Applicant: Villanova University, Villanova, PA (US)

(72) Inventors: Steven G. Schon, Strafford, PA (US); Aaron P. Wemhoff, Media, PA (US); Alfonso Ortega, Villanova, PA (US)

(73) Assignee: Villanova University, Villanova, PA (US)

(21) Appl. No.: 16/593,117

(22) Filed: Oct. 4, 2019

Related U.S. Application Data
(60) Provisional application No. 62/741,819, filed on Oct. 5, 2018.

(51) Int. Cl. H05K 7/20; F25B 27/00

(52) U.S. Cl. CPC H05K 7/20354; H05K 7/20318; F28F 23/00; F25B 27/005; H05K 7/20509

(57) ABSTRACT

A system and a method are provided for cooling devices and recovering waste heat. A plurality of heat absorption devices in direct or indirect thermal contact with a plurality electronic devices, and comprise channels to receive an evaporable working liquid, which becomes a first 2-phase mixture having a first liquid portion and a first vapor portion upon absorption of heat from the devices. At least one compressor compresses the first vapor portion to form a compressed vapor having elevated pressure and temperature. At least one heat exchanger condenses the compressed vapor to liquid so as to release the heat. An expansion device is used to expand the liquid to provide a second 2-phase mixture comprising a second liquid portion and a second vapor portion. In at least one vapor-liquid separator, the first liquid portion and the second liquid portion are fed back to the plurality of heat absorption devices. The second vapor portion is fed back to the at least one compressor.

### PRIORITY CLAIM AND CROSS-REFERENCE

This application claims the benefit of U.S. Provisional Application No. 62/741,819, filed Oct. 5, 2018, which application is expressly incorporated by reference herein in its entirety.

### STATEMENT REGARDING FEDERAL SPONSORED RESEARCH

This invention was made with government support under Grant No. 1738782, awarded by the National Science Foundation.

### FIELD OF THE INVENTION

The disclosure relates to systems and methods for cooling generally. More particularly, the disclosed subject matter relates to a system and a method for cooling devices such as electronics and recovering the rejected heat in a useful form.

### BACKGROUND

Electronic devices inherently generate waste heat, which must be removed to prevent a run-away temperature rise and failure of the devices. Because the electronic devices generally have relatively low operating temperature limits (typically less than 80° C.) yet high heat fluxes (on the order of tens to hundreds of watts per square centimeter), the heat must be removed using low-temperature cooling means to facilitate the heat transfer (typically cooler than 20-50° C.). The waste heat is therefore rejected at the low temperatures of the cooling media, and thus is so degraded in energy quality, that the heat generally cannot be efficiently recovered for useful purposes.

Facilities with large numbers of electronic devices consume large amounts of electric power, and the unrecovered waste heat represents a substantial operating expense. In particular, data centers typically have hundreds to thousands of data servers, with aggregate power consumption and waste heat rejection rates ranging from tens of kilowatts to hundreds of megawatts.

From an energy consumption perspective, large-scale data centers consume as much as 100 times more energy per square meter than typical commercial or residential spaces. In aggregate, data centers consume more than two percent of the world-wide electricity production.

Electronic devices have traditionally been cooled by various means, rejecting the waste heat to the ambient air or cooling water, without further re-use of the low-quality waste heat. Because of the impracticality of directly cooling compact electronics with ambient air or cooling water, intermediate cooling loops may be used to facilitate easy transport of the waste heat from the electronic devices to the final heat sink media. These intermediate loops consume additional power (e.g., for pumps, blowers, and refrigeration systems), and add to the system complexity and cost. In addition, the intermediate cooling loops operate at lower temperatures than the primary device coolers and thus further degrade the quality of the waste heat.

### SUMMARY

The present disclosure provides a system and a method for recovering and upgrading waste heat while cooling electronic devices by coupling gravity-driven 2-phase cooling with vapor compression.

Heat dissipated from facilities with many electronic devices, for example, data centers, is typically low-grade energy, and is rejected, representing a substantial loss of value.

Efficient cooling of electronic components, especially data center equipment, is achieved while simultaneously upgrading the quality of the removed heat by coupling 2-phase cooling loops with compressors operating as heat pumps to upgrade the rejected heat; the higher-grade energy can be put to useful purposes, for example, for space heating, or driving an absorption or adsorption chiller system.

Low-pressure working fluid (refrigerant) is partially evaporated at low temperatures, cooling multiple electronic devices, using either heat absorbers (cold plates) in thermal contact with the devices, or using indirect heat exchangers (radiators) to cool air that in turn is used to cool the electronic devices. The 2-phase mixtures from the multiple cold plates or radiators are separated in a common or single vapor/liquid separator vessel, with the vapor going to a compressor, discharging a higher-temperature, high-pressure vapor, and condensing at higher temperatures compared to a compressor-less system, allowing the heat to be used for useful purposes. After condensation, the refrigerant is flash-expanded to the lower operating pressure and temperature, returning the cool 2-phase mixture back to the separator. The un-evaporated liquid returning from the cold plates or radiators, along with the liquid portion of the flash-expanded fluid, combine as the cool liquid feed, which is returned by gravity flow to the cold plates and/or radiators via a common liquid supply manifold.

It is preferable to use cold plates or radiators with internal microchannel structures for the evaporation of the working fluid, as these have the lowest thermal resistances of the various evaporator geometries.

While any suitable refrigerant may be used as the working fluid, it is preferred to use dielectric fluids which have low ozone-depletion potential, low global-warming potential, low toxicity, and are not ignitable at ambient conditions.

The upgraded-quality (higher-temperature) waste heat in the form of hot pressurized vapor discharged from the compressor can be used for any useful purpose, including, but not limited to: process or space heating, and the production of chilled water or air, for example, by means of an absorption chiller or adsorption chiller (refrigeration) system.

The fraction of recoverable waste heat can be increased by using an economizer that pre-heats and super-heats the low pressure vapor to the compressor by sub-cooling the high-pressure condensed working fluid.

The amount of recoverable waste heat can be augmented by using a direct or indirect solar heater to further pre-heat and/or super-heat the low pressure vapor to the compressor. An indirect solar heat can use either a pumped or passive (liquid thermosiphon) secondary heat transfer fluid loop. If the secondary fluid may be heated by direct solar radiation via transparent sections of the solar heater, it is desirable to use a secondary fluid that maximizes the solar spectral absorption, e.g. using a so-called nano-fluid containing several types of nanoparticles, each type of which is “tuned” to absorb a selected band of the solar spectrum.

In some embodiments, a system comprises a plurality of heat absorption devices, at least one compressor, at least one heat exchanger, an expansion device, and at least one vapor-liquid separator.

The plurality of heat absorption devices such as cold plates and/or radiators are in thermal communication with a plurality electronic devices, for example, devices in a data center. Each of the plurality of heat absorption devices comprises at least one channel configured to receive and circulate an evaporable working liquid (e.g., a refrigerant). The term “in thermal communication with” used herein may be understood that the components are “in proximity to or in contact with” each other to thermally interact with each other. The working liquid is configured to become a first 2-phase mixture having a first liquid portion and a first vapor portion upon absorption (either directly or indirectly) of heat from the plurality of electronic devices.

The at least one compressor is configured to combine the first vapor portion from the plurality of heat absorption devices and compress the first vapor portion to form a compressed vapor having an elevated pressure and an elevated temperature. The at least one heat exchanger is configured to condense the compressed vapor to liquid at the elevated pressure so as to release and recover the heat. The expansion device having a valve or an orifice is configured to expand the liquid at the elevated pressure to provide a second 2-phase mixture at a reduced pressure comprising a second liquid portion and a second vapor portion. The at least one vapor-liquid separator is configured to feed the first liquid portion and the second liquid portion back to the plurality of heat absorption devices, and to supply the second vapor portion back to the at least one compressor.

The components of the system are fluidly coupled together in a flowing direction of the working liquid, and the first and the second 2-phase mixtures.

In some embodiments, the system is in a closed loop and the working fluid is in gravity-driven circulation.

In some embodiments, each of the plurality of heat absorption devices is selected from the group consisting of a cold plate, a radiator, and a combination thereof. The plurality of heat absorption devices may include both cold plates and radiators in some embodiments.

In some embodiments, the system further comprises an internal heat exchanger (“economizer”) configured to further heat the first vapor portion from the plurality of heat absorption devices, and further cool the liquid at the elevated pressure from the at least one heat exchanger before the liquid is supplied to the expansion device.

In some embodiments, the system further comprises a solar powered heater configured to further heat the first vapor portion before the first vapor is provided to at least one compressor. The solar powered heater may be directly heated by solar radiation. In some embodiments, the solar powered heater comprises a secondary heat fluid loop comprising a secondary heat transfer fluid, which may include a nano-fluid including dispersed nanoparticles.

The system may further comprise a sub-system configured to utilize the heat recovered from the at least one heat exchanger.

In another aspect, the present disclosure provides a method for recovering waste heat while cooling devices. In some embodiments, such a method comprises the steps described herein.

An evaporable working liquid is provided (or fed) to a plurality of heat absorption devices in proximity to or in contact with a plurality electronic devices. Each of the plurality of heat absorption devices contains at least one channel. The working liquid becomes a first 2-phase mixture having a first liquid portion and a first vapor portion upon absorption of heat (either directly or indirectly) from the plurality of electronic devices.

The first vapor portion from the plurality of heat absorption devices are combined and compressed using at least one compressor configured to form a compressed vapor having an elevated pressure and an elevated temperature. The compressed vapor is condensed to liquid at the elevated pressure using at least one heat exchanger configured so as to release and recover the heat. The liquid at the elevated pressure is then expanded using an expansion device having a valve or an orifice to provide a second 2-phase mixture at a reduced pressure, comprising a second liquid portion and a second vapor portion.

The first liquid portion and the second liquid portion are fed back to the plurality of heat absorption devices in at least one vapor-liquid separator. The second vapor portion is supplied back to the at least one compressor.

In some embodiments, the system is in a closed loop and the working fluid is in gravity-driven circulation. In some embodiments, an internal heat exchanger (“economizer”) is used to further heat (preheat and/or superheat) the first vapor portion, and further cool (sub-cool) the liquid at the elevated pressure from the at least one heat exchange before the liquid is supplied to the expansion device.

The method may further comprise further heating the first vapor portion using a solar powered heater before the first vapor is provided to at least one compressor. The solar powered heater is directly heated by solar radiation, or comprises a secondary heat fluid loop comprising a secondary heat transfer fluid.

The method further comprises utilizing the heat recovered from the at least one heat exchanger. The uses can be process heating, space heating, and driving the regenerator for an absorption or adsorption chiller, mechanical or thermoelectric generator, any other uses or combination thereof.

### BRIEF DESCRIPTION OF THE DRAWINGS

The present disclosure is best understood from the following detailed description when read in conjunction with the accompanying drawings. It is emphasized that, according to common practice, the various features of the drawings are not necessarily to scale. On the contrary, the dimensions of the various features are arbitrarily expanded or reduced for clarity. Like reference numerals denote like features throughout specification and drawings. The exemplary figures illustrate the heat absorption devices as being in direct thermal contact with the heat-generating electronics, thereby transferring the heat directly to the heat absorption device (evaporator). However, it is further understood that alternatively, the heat from the heat generating electronics may be transferred indirectly to the heat absorption device, e.g., via air circulated between an air-cooled heat sink in direct thermal contact with the heat-generating electronics, and air-fluid heat exchanger (radiator) containing the refrigerant, thereby serving as the heat absorption device.

FIG. 1 illustrates a first exemplary system for 2-phase cooling of electronics without heat recovery in accordance with some embodiments.

FIG. 2 illustrates a second exemplary system for 2-phase cooling of electronics without heat recovery in accordance with some embodiments.

FIG. 3 illustrates a first exemplary system for upgrading the waste heat via vapor recompression while cooling electronic devices in accordance with some embodiments.

FIG. 4 illustrates a second exemplary system including an economizer, for upgrading the waste heat via vapor recompression while cooling electronic devices in accordance with some embodiments.

FIG. 5 illustrates a third exemplary system including an economizer and a solar heater, for upgrading the waste heat via vapor recompression while cooling electronic devices in accordance with some embodiments.

FIGS. 6-7 illustrate a fourth and a fifth exemplary systems for upgrading the waste heat via vapor recompression including an economizer and a solar heater, while cooling electronic devices, in accordance with some embodiments.

FIG. 8 illustrates a sixth exemplary system for upgrading the waste heat via vapor recompression while cooling electronic devices and equipment with indirect 2-phase cooling in accordance with some embodiments.

FIG. 9 illustrates a seventh exemplary system for upgrading the waste heat via vapor recompression while cooling electronic devices and equipment with a hybrid (including both direct and indirect) 2-phase cooling in accordance with some embodiments.

FIG. 10 is a flow diagram illustrating an exemplary method in accordance with some embodiments.

FIG. 11 is a flow diagram generated by ASPEN PLUS® simulation/modeling software showing electronics cooling with waste heat upgraded for process or space heating in some embodiments.

FIG. 12 is another flow diagram generated by ASPEN PLUS® simulation/modeling software showing electronics cooling with waste heat upgraded for driving absorption chiller in some embodiments.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” refer to a relationship wherein structures are secured or attached to one another either directly or indirectly through intervening structures, as well as both movable or rigid attachments or relationships, unless expressly described otherwise.

For purposes of the description hereinafter, it is to be understood that the embodiments described below may assume alternative variations and embodiments. It is also to be understood that the specific articles, compositions, and/or processes described herein are exemplary and should not be considered as limiting.

In the present disclosure the singular forms “a,” “an,” and “the” include the plural reference, and reference to a particular numerical value includes at least that particular value, unless the context clearly indicates otherwise. Thus, for example, a reference to “a cold plate” is a reference to one or more of such structures and equivalents thereof known to those skilled in the art, and so forth. When values are expressed as approximations, by use of the antecedent “about,” it will be understood that the particular value forms another embodiment. As used herein, “about X” (where X is a numerical value) preferably refers to ±10% of the recited value, inclusive. For example, the phrase “about 8” preferably refers to a value of 7.2 to 8.8, inclusive; as another example, the phrase “about 8%” preferably (but not always) refers to a value of 7.2% to 8.8%, inclusive. Where present, all ranges are inclusive and combinable. For example, when a range of “1 to 5” is recited, the recited range should be construed as including ranges “1 to 4”, “1 to 3”, “1-2”, “1-2 & 4-5”, “1-3 & 5”, “2-5”, and the like. In addition, when a list of alternatives is positively provided, such listing can be interpreted to mean that any of the alternatives may be excluded, e.g., by a negative limitation in the claims. For example, when a range of “1 to 5” is recited, the recited range may be construed as including situations whereby any of 1, 2, 3, 4, or 5 are negatively excluded; thus, a recitation of “1 to 5” may be construed as “1 and 3-5, but not 2”, or simply “wherein 2 is not included.” It is intended that any component, element, attribute, or step that is positively recited herein may be explicitly excluded in the claims, whether such components, elements, attributes, or steps are listed as alternatives or whether they are recited in isolation.

The present disclosure provides a system and a method for recovering and upgrading waste heat while cooling electronic devices by coupling gravity-driven 2-phase cooling with vapor compression.

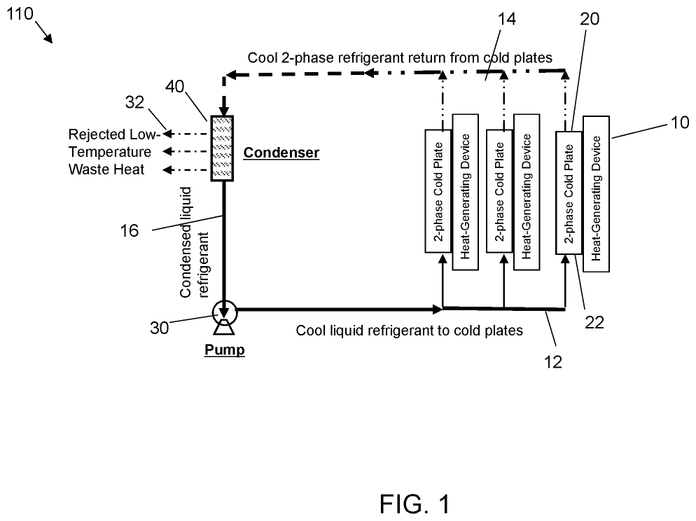

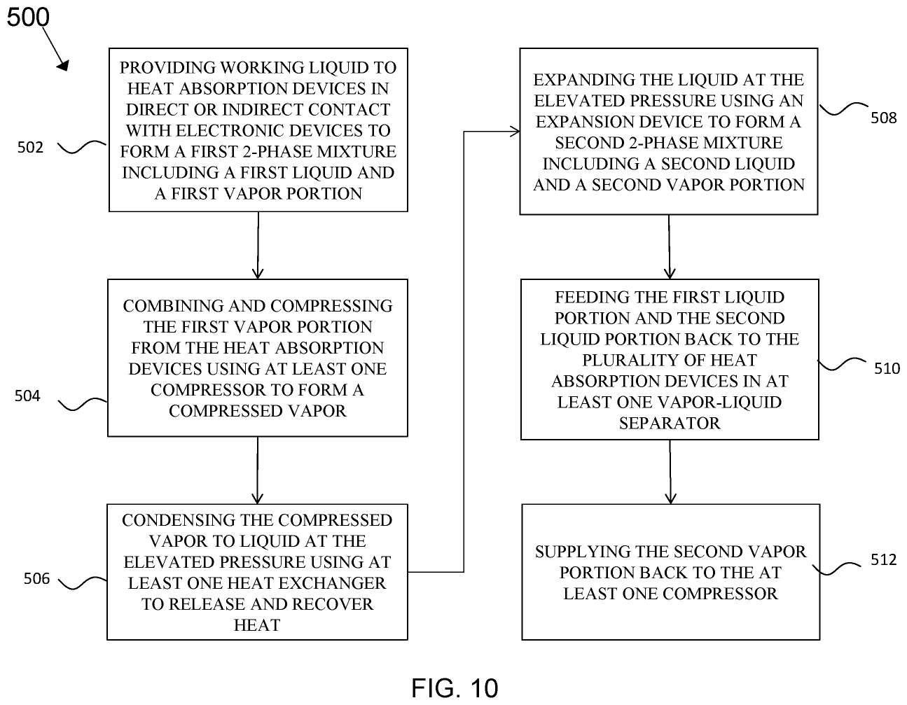

In FIGS. 1-9, like items are indicated by like reference numerals, and for brevity, descriptions of the structure, provided above with reference to the preceding figures, are not repeated. The method described in FIG. 10 is described with reference to the exemplary structure described in FIGS. 1-9. Unless indicated otherwise, the components in FIGS. 1-9 may be aligned horizontally or vertically, at different heights.

In 2-phase cooing systems in the field of cooling electronics, the devices are cooled (either directly or indirectly) by evaporating a working fluid, which can afterwards be condensed and re-used. Evaporative cooling relies on the boiling mode, and has the advantages of higher heat transfer coefficients (better heat transfer) per unit of fluid flow rate of the coolant fluid, and also requires much less coolant flow. The majority of heat is latent heat absorbed through vaporization of the boiling fluid, rather than the sensible heat (heat capacity) of a single-phase liquid or gas. 2-phase cooling means include wick-type heat pipes, loop heat pipes, evaporative spray cooling, evaporative immersion cooling, the like and the combinations thereof. The heat transfer between the electronic devices can be enhanced using micro-structured surfaces, such as microchannels, pin-fins, capillary wick structures, the like, and any combinations thereof, where the evaporating fluid boils.

If a gaseous or 2-phase cooling is used, the quality of the waste heat, in the form of the gas or vapor, can be increased by mechanical vapor compression, i.e., the heat pump principle. Vapor compression and expansion can be used to cool electronic devices; however, these substantially function as Rankine-cycle type refrigeration loops, wherein the device cooler (cold plate) functions substantially as the low-pressure evaporator, but the heat rejected at the high-pressure condenser is not recovered. In some systems, closed-loop 2-phase cooling of electronics is combined with vapor recompression for waste heat recovery. However, in all of these systems, the flow of the vaporizable working fluid to the evaporative coolers is driven by a pump and/or a compressor, adding to the complexity, cost, and power consumption of the system.

It is therefore desirable to provide a means for passively cooling multiple electronic devices with low-temperature primary cooling means without requiring coolant circulation pumps or compressors, transferring the heat directly to a final heat sink without intermediate heat transfer loops, and upgrading the quality of removed waste heat to a higher temperature (than the normal operating temperatures of cooling media), so that the waste heat can be reused for useful purposes.

It is also desirable to augment the recoverable high-quality heat by sustainable means, e.g. renewable solar energy, particularly in geographical locations having high solar insolation and a need for chilling or air conditioning.

In accordance with a broad aspect, the present disclosure provides a system comprising one or more parallel 2-phase (evaporative) coolers operating in closed-loop circulation mode used to cool one or more electronic devices (either directly or indirectly), wherein the 2-phase fluid mixture exiting the one or more coolers is sent to a chamber, wherein the vapor is separated from the liquid, the vapor is sent to a compressor, thereby raising the pressure and temperature of the vapor, condensing the hot vapor and using the heat for useful purposes, flash-expanding and thereby cooling the condensed fluid, re-combining the liquid portion of the cooled flashed fluid with the liquid in the chamber, and returning the cool liquid mixture by gravity to the one or more evaporative coolers.

In accordance with some embodiments, one or more parallel 2-phase (evaporative) coolers operate in closed-loop circulation mode. The vapor from the 2-phase mixture exiting the one or more coolers is separated from the saturated liquid emerging from the liquid. The vapor is sent to a compressor, thereby raising the pressure and temperature of the vapor. The heated vapor is sent to one or more condensers where the vapor is fully condensed, imparting the higher-temperature heat that is transferred to an end user for useful purposes. The condensed liquid is flash-expanded, thereby cooling the condensed fluid. The liquid portion of the cooled flashed fluid with the liquid is re-combined with the liquid separated liquid from the 2-phase mixture exiting the one or more coolers. The combined cool liquid mixture returns to the one or more evaporative coolers.

The present disclosure also provides a process and means for cooling a plurality of electronic devices using closed-loop 2-phase cooling with gravity-driven circulation comprising a plurality of heat absorption devices such as cold plates and/or radiators that operate in the boiling mode. An evaporable working fluid is supplied as a liquid to the plurality of cold plates and/or radiators. The plurality of cold plates and/or radiators are in direct or indirect thermal contact with the plurality of electronic devices. Heat generated by the plurality of electronic devices is absorbed by the plurality of cold plates and/or radiators, transferred to the working fluid flowing inside the cold plates and/or radiators, causing a portion of the working fluid to evaporate (boil), resulting in 2-phase mixtures exiting the plurality of cold plates and/or radiators, thereby removing and transporting the heat away from the plurality of electronic devices. The vapor portion of the 2-phase mixtures are combined and compressed to an elevated pressure and temperature by mechanical means using one or more compressors, thereby increasing the temperature and quality of the heat. The hot, compressed vapor is sent to the one or more heat exchangers, where the vapor is condensed back to liquid at elevated pressure, releasing high-quality heat at an elevated temperature. The heat removed is recovered and available for useful purposes including, but not limited to, process heating, space heating, driving the regenerator for an absorption or adsorption chiller, mechanical or thermoelectric generator, or any combination thereof.

The high-pressure liquid exiting the heat exchangers is let-down by flash-expansion means, resulting in a cold, 2-phase mixture at substantially the low operating pressure of the working fluid supplying the plurality of cold plates.

The 2-phase mixture is combined with and provides a cooling effect to the incoming 2-phase mixtures returning from the plurality of cold plates and/or radiators, partially condensing the low-pressure vapor and maintaining the liquid being supplied to the plurality of cold plates and/or radiators at the desired low temperature. The combined vapor returns to the one or more compressors while the combined liquid returns to the plurality of cold plates.

In some embodiments, the means for cooling a plurality of electronic devices using closed-loop 2-phase cooling is accomplished by gravity-driven circulation comprising a plurality of heat absorption devices (cold plates and/or radiators) that operate in the boiling mode.

In some embodiments, an evaporable working fluid is supplied as a liquid at a substantially constant elevation to the plurality of cold plates and/or radiators by means of one or more reservoirs (head tanks) connected to liquid supply manifold connected to the plurality of cold plates. The liquid working fluid flows by gravity to the plurality of cold plates and/or radiators. The plurality of cold plates and/or radiators are in direct or indirect thermal contact with the plurality of electronic devices.

Heat generated by the plurality of electronic devices is absorbed by the plurality of cold plates and/or radiators, transferred to the working fluid flowing inside the cold plates, causing a portion of the working fluid to evaporate (boil), resulting in 2-phase mixtures exiting the plurality of cold plates and/or radiators, thereby removing and transporting the heat away from the plurality of electronic devices, and;

In some embodiments, the 2-phase mixtures exiting the one or more cold plates and/or radiators are sent to the one or more reservoirs, wherein the vapor is separated from the liquid. The separated vapor is compressed to an elevated pressure and temperature by mechanical means using one or more compressors, thereby increasing the temperature and quality of the heat.

The higher-pressure hot working fluid vapor is used as heat source for useful means, including, but not limited to, process heating, space heating, driving the regenerator for an absorption or adsorption chiller, mechanical or thermoelectric generator, or any other suitable uses or combination thereof. The higher-pressure vaporized working fluid is condensed after transferring the useful heat.

The higher-pressure condenser working fluid is flash-expanded and cooled. The flash-expanded cool working fluid is returned to the one or more head tanks, wherein the vapor and liquid portions of the flash-expanded working fluid is recombined with the respective vapor and liquid separated from the 2-phase mixtures exiting the plurality of cold plates and/or radiators. The combined vapor returns to the one or more compressors while the combined liquid returns to the plurality of cold plates and/or radiators.

In some embodiments, one or more of the plurality of electronic devices and cold plates and/or radiators are at different elevations with respect to each other, resulting in unequal supply pressures to the various cold plates and/or radiators, the incoming pressures to the one or more cold plates and/or radiators may be adjusted and preferably equalized by restriction means such as orifices or valves with suitably match flow coefficients.

In some embodiments, the plurality of electronic devices are information technology components, such as those used in a data center. The 2-phase mixture from each of the plurality of cold plates and/or radiators returns to one or more common phase separators with serves as the one or more head tanks, and the combined vapors are sent to the one or more compressors.

In some embodiments, the 2-phase mixture from each of the plurality of cold plates and/or radiators returns to one or more common headers, wherein the liquid separates by gravity and is separately returned to the one or more head tanks. The combined vapor is sent to the one or more compressors, either directly or via the vapor space of the head tank.

In some embodiments, the vapors going to the one or more compressors are superheated by heat exchange means using the hot condensed liquid exiting the one or more condensing heat exchangers, thereby further cooling the condensed liquid prior to the flash-expansion step.

The vapor sent to the one or more compressors may be pre-heated and super-heated by a heat exchanger (“economizer”) that transfers heat from and thereby sub-cools the liquid exiting the condenser for the evaporative working fluid, prior to its flash-expansion. The vapor entering the compressor also may be pre-heated and super-heated by a solar-powered heater. For example, the solar powered heater is heated directly by solar radiation in some embodiments. In some embodiments, the solar powered heater is heated indirectly by a secondary heat transfer fluid loop, which is heated by a separate solar heater.

In some embodiments, the circulation of the secondary heat transfer loop for the indirect solar heater is driven by active means, such as a pump. The circulation of the secondary heat transfer loop for the indirect solar heater may be driven by passive means, such as natural circulation or the thermosiphon principle. In some embodiments, the fluid used in the secondary heat transfer loop of a heated solar-powered vapor super-heater is heated by direct solar radiation via transparent sections of the solar heater. The secondary heat transfer fluid may have high absorptivity of solar radiation.

In some embodiments, the evaporable working fluid is a refrigerant as described herein. The refrigerant may also be a dielectric fluid, i.e., substantially electrically non-conductive. In some embodiments, the refrigerant is substantially non-flammable gas at ambient conditions. The refrigerant may have low ozone depletion potential (ODP) in some embodiments. The refrigerant may have low global warming potential (GWP). The refrigerants may be any chemicals described herein or mixtures thereof.

The secondary heat transfer fluid may be a nano-fluid containing dispersed nanoparticles, which absorb and are warmed by the solar energy, and which conductively transfer the heat to the carrier fluid. In some embodiments, the secondary heat transfer fluid contains two or more distinct types of dispersed nanoparticles, each type of which is “tuned” to absorb a selected band of the solar spectrum, wherein the various nanoparticles which absorb and are warmed by their respective solar energy spectral bands, respectively conductively transfer the heat to the carrier fluid.

In some embodiments, the liquid supply and 2-phase mixture return connections of the plurality of cold plates are connected using isolation valves, to facilitate ready isolation and removal of individual electronic devices and their attached cold plates, without having to shut-down or disrupt the operation of the rest of the system.

In some embodiments, the liquid supply and 2-phase mixture return connections of the plurality of cold plates are connected using leak-less (“dry-break”) quick-disconnect fittings, to facilitate ready removal of individual electronic devices and their attached cold plates, without having to shut-down or disrupt the operation of the rest of the system.

The upgraded-quality (higher-temperature) waste heat in the form of hot pressurized vapor discharged from the compressor can be used for any useful purpose, including, but not limited to:

(1) Process heating, by means a heat exchanger that serves as the condenser for the evaporative working fluid;

(2) Space heating, by means of air- or circulating water-cooled exchanger that serves as the condenser for the evaporative working fluid; and

(3) Production of chilled water or air, by means of an absorption- or adsorption-chiller (refrigeration) system, whereby the waste heat is used to regenerate the absorber fluid or adsorbent, with the regenerator serving as the condenser for the evaporative working fluid.

In some embodiments, the high-quality heat removed by the one or more condensing heat exchangers is used for process heating or space heating. The high-quality heat is transferred to water, air or any other suitable heat transfer medium for use as the process or space heating medium.

In some embodiments, the high-quality heat removed by the one or more condensing heat exchangers is the heating means required to regenerate/re-concentrate the working (absorption) fluid of an absorption chiller system, or the heating means required to regenerate/re-concentrate the adsorbent medium fluid of an adsorption chiller system. In some embodiments, the high-quality heat removed by the one or more condensing heat exchangers is the heating means to drive a mechanical or thermo-electric power generator.

Depending on the evaporative fluid (refrigerant) and the operating pressures, the operating temperatures of the fluid boiling in the evaporators can be at or below 20-40° C., while the rejected heat can be upgraded to greater than 70-120° C. at the compressor outlet. Under these conditions, the coefficient of performance (COP), herein defined as the ratio of recovered useful heat or chilling power at the elevated condensing temperature, divided by the additional shaft power supplied to the compressor, can be well in excess of unity, i.e., the total useful heat or chilling delivered exceeds the compression power used to upgrade the waste heat.

While any suitable vaporizable fluid may be used, for arrays of electronic devices that are in rooms or other enclosed spaces, particularly those visited by people (e.g., in data centers), the evaporative working fluid preferably has the following qualities, for compatibility with common heat exchanger and compressor materials of construction, and to minimize the potential for harm in the event of a leak:

(1) Dielectric fluid (i.e., electrically non-conducting), so as to prevent electrical shocks and circuit damage;

(2) Normal boiling point below room temperature, which will evaporate into the air, rather than puddling on the electronic equipment;

(3) Non-toxic by inhalation or skin contact;

(4) Non-flammable at ambient temperatures;

(5) Low ozone depletion potential (ODP);

(6) Low global warming potential (GWP); and

(7) Compatible with copper, aluminum, and common elastomeric seal materials

Refrigerants that meet these criteria include, but are not limited to, pure components or mixtures comprising HFO-1233zd, HFO-1234yf, HFO-1234ze, carbon dioxide, any other suitable liquid or gas, or any combination thereof.

The fraction of recoverable waste heat or chilling power can be increased by using an economizer that pre-heats and super-heats the low pressure vapor to the compressor by sub-cooling the high-pressure condensed working fluid.

The amount of recoverable waste heat or chilling power can also be augmented by using a direct or indirect solar heater to further pre-heat and/or super-heat the low pressure vapor to the compressor.

In some embodiments, an indirect solar vapor heater may include a solar absorber to heat a secondary heat transfer fluid, which in turn heats a liquid/gas heat exchanger to heat the vapor to the compressor. This physically decouples the primary heat recovery system from the solar absorber.

The solar-heated secondary heat transfer fluid loop may be operated either actively (pumped) or passively, using the thermosiphon principle. In the latter, the vapor super-heater is elevated above the solar absorber; the density difference between the hot (lower density) fluid exiting the solar absorber, and the cooler (higher density) fluid exiting the vapor super-heater drives the secondary fluid flow via natural circulation.

In some embodiments, the secondary fluid may be heated by direct solar radiation via transparent sections of the solar heater, as may be practiced with concentrating solar heaters. In those situations, it is desirable to use a secondary fluid that has high absorptivity of solar radiation, to maximize the exit temperature of the heated secondary fluid. A particularly effective means to do this is to employ a so-called nano-fluid, comprising dispersed nanoparticles, as the particles absorb and are warmed by the solar energy, and conductively transfer the heat to the carrier fluid. The absorbable solar energy can be maximized by using two or more distinct types of nanoparticles, each type of which is “tuned” to absorb a selected band of the solar spectrum (e.g., infrared, visible, ultraviolet, or a combination thereof). This allows more solar energy to be harvested than can be achieved by a nano-fluid including only one type of particles, as any given particle type has a maximal absorbance over a relatively narrow band of the solar spectrum.

The advantages of the system and the method provided in the present disclosure include passive facilitation of the low-temperature direct or indirect cooling of assemblies of electronic devices without requiring circulation pumps or secondary heat transfer loops, while also efficiently upgrading the quality of the waste heat, so that it can be recovered and used for useful purposes. In addition to reducing operating costs the system of the present disclosure is environmentally beneficial (“green”), as the recovered useful waste heat correspondingly reduces the energy (including conversion inefficiencies) that would otherwise be required to supply the equivalent useful heat or work. The “green” benefits are synergistic when the heat recovery is augmented by solar energy. In geographical locations having high solar insolation and a need for chilling or air conditioning, the combination of the vapor recompression heat recovery and solar superheating of the vapor to the compressor can maximize both the heat recovery efficiency and increase delivered cooling power beyond what a comparable stand-alone solar-driven chiller system can achieve.

It is to be understood that other aspects of the present disclosure will become readily apparent to those skilled in the art from the following detailed description; herein various embodiments of the present disclosure are shown and described by way of illustration. As will be realized, the present disclosure is capable for other and different embodiments and its several details are capable of modification in various other respects, all without departing from the spirit and scope of the present disclosure.

Accordingly the drawings and detailed description are to be regarded as illustrative in nature and not as restrictive. While the figures refer to “cold plates” 22, which are heat absorption devices 20 in direct thermal contact with the electronics 10, it is understood that alternatively, the cold plates 22 may be substituted with air-cooled heat sinks and air-heated evaporators (radiators) 24, wherein the heat from the electronics is transferred (indirectly) by the warmed air to one or more evaporators, which in turn cool the air. The cooled air can be recirculated back to the heat sinks. As illustrated and/or described in FIGS. 1-9, a plurality of heat absorption devices 20 may include cold plates 22 for direct cooling, radiators 24 for indirect cooling, or any combination thereof in a hybrid mode.

In FIGS. 1-9, unless indicated otherwise, the components in the systems are in thermal communication with each other, and are fluidly connected with each other if needed. As shown in arrowed lines, the fluids and vapors are transported in pipes. For illustration purposes, the fluids are shown in solid arrowed lines while the vapors are shown in dashed arrowed lines.

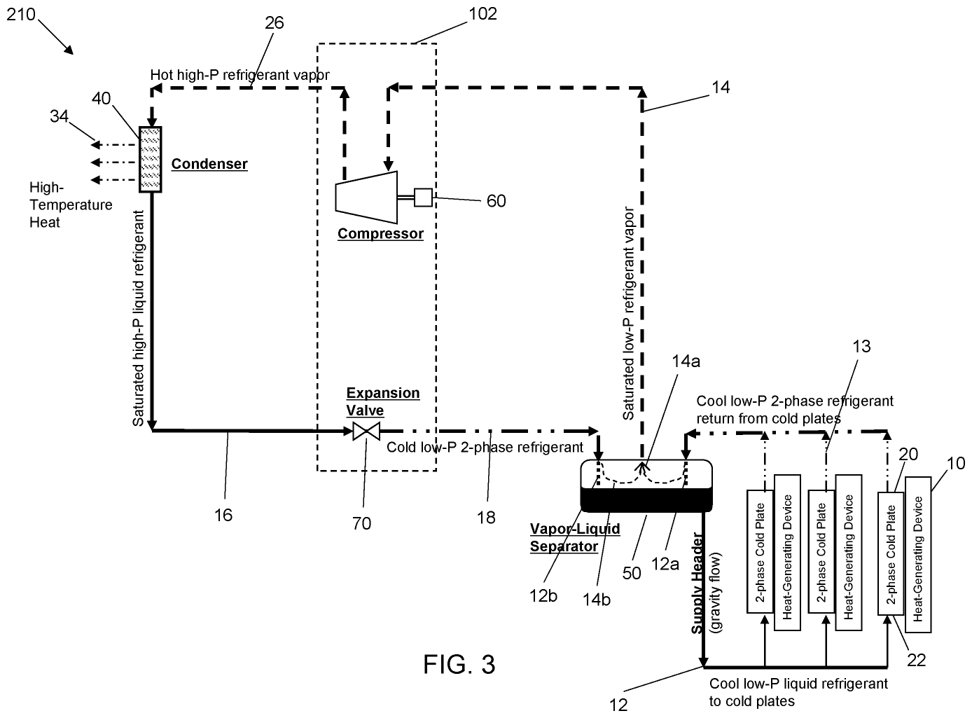

In FIGS. 3-9, the first dashed area 102 is used to highlight the components for vapor compression such as heat pump, and the second dashed area 104 area is used to highlight the components associated with supplemental solar heating. In some embodiments, the dashed areas 104 and 106 may be located separately from a room housing the electronic devices or equipment.

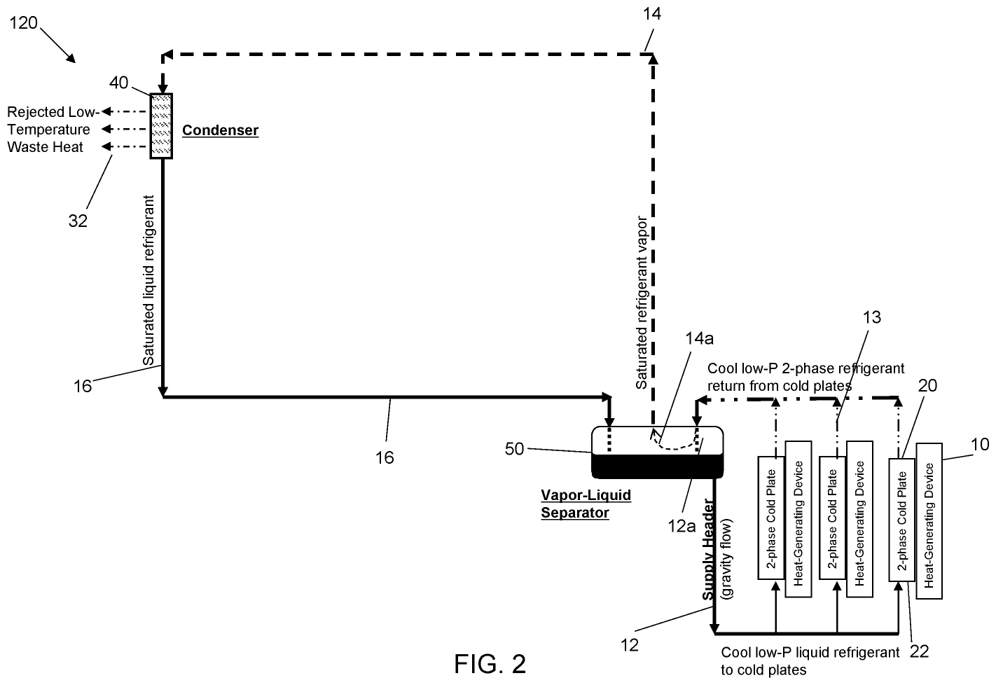

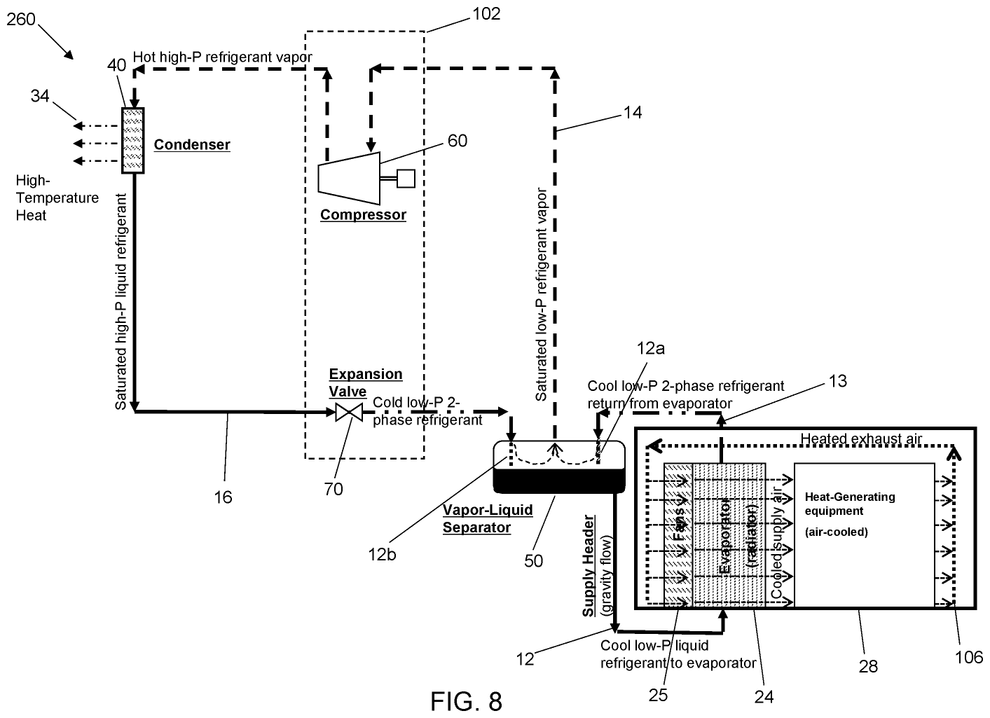

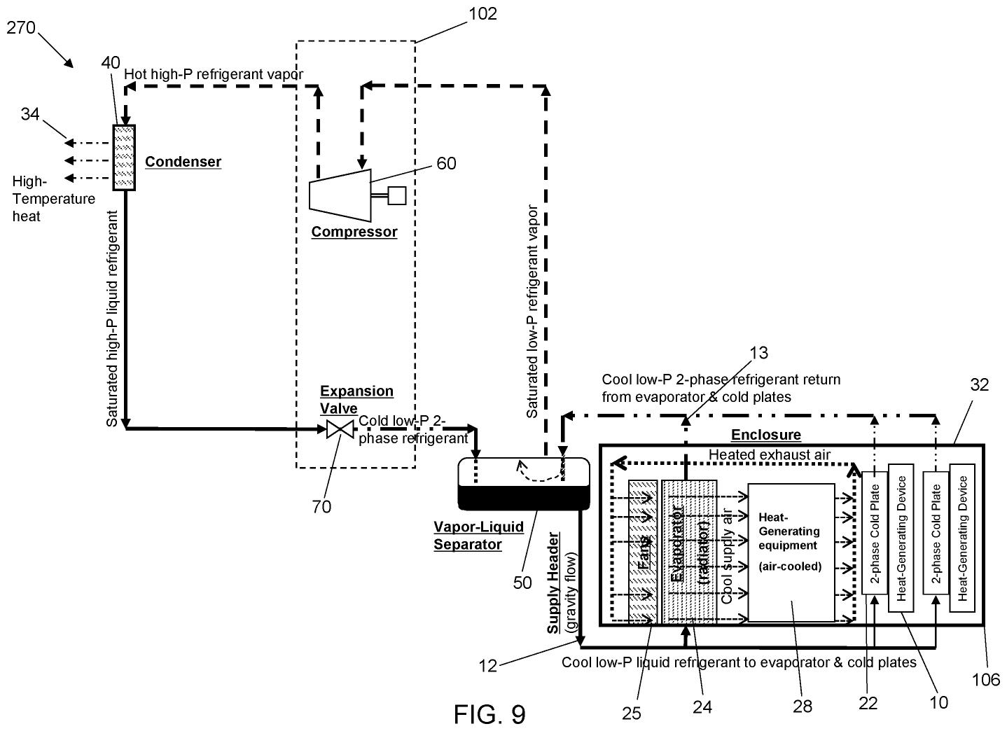

FIGS. 1-2 describe two exemplary systems 110, 120 with 2-phase cooling of electronics without heat recovery. Referring to FIGS. 1-2, one or more parallel evaporative coolers, also referred to as heat absorption devices 20, such as cold plates 22, radiators 24 (as illustrated in FIGS. 8-9, not shown in FIGS. 1-2), or a combination thereof, operate in closed-loop circulation mode, wherein the heat is removed from the electronic devices 10 by partially evaporating a working fluid 12 at low to moderate temperatures. The vapor 14 from the cold plates 22 (or radiators) is condensed, rejecting the heat to the condenser 40 cooling media as low-grade (or low temperature) waste heat 32. The condensed working fluid 16 is returned to the cold plates 22 (or radiators) to complete the cycle.

In some embodiments, the evaporative working fluid 12 used has the following qualities, for compatibility with common heat exchanger and compressor materials of construction, and to minimize the potential for harm in the event of a leak:

(1) Dielectric fluid (i.e. electrically non-conducting), so as to prevent electrical shocks and circuit damage;

(2) Normal boiling point below room temperature, which will evaporate into the air, rather than puddling on the electronic equipment;

(3) Non-toxic by inhalation or skin contact;

(4) Non-flammable at ambient temperatures;

(5) Low ozone depletion potential (ODP); and

(6) Compatible with copper, aluminum, and common elastomeric seal materials

In some embodiments, working fluids 12 that meet these criteria include, but are not limited to, refrigerants in the form of pure components or mixtures comprising HFC-1234a, HFC-235fa, and any combination thereof. The evaporative working fluid 12 has the above-defined qualities, and, in addition, have low global warming potential (GWP). Working fluids that meet these criteria include, but are not limited to, refrigerants in the form of pure components or mixtures comprising HFO-1233zd, HFO-1234yf, HFO-1234ze, carbon dioxide, any other suitable liquid or gas, or combination thereof.

In some embodiments, depending on the evaporative fluid (refrigerant) and the operating pressures, the operating temperatures of the fluid boiling in the evaporators can be at or below 20-40° C., while the rejected heat can be upgraded to greater than 70-120° C. at the compressor outlet.

FIG. 1 shows the exemplary system 110 with a 2-phase cooling loop using pumped circulation of the working fluid 12, in which a pump 30 is used to pump the working liquid 12 to the cold plates 22 (or radiators 24).

FIG. 2 shows the exemplary system 120 with a gravity-driven 2-phase cooling loop using passive circulation of the working fluid 12, operating on the thermosiphon principle, using the density difference between the liquid 12 and the vapor 14 to drive the circulation through the cold plates 22 (or radiators 24). Vapor 14 is separated from the liquid 12 in a first 2-phase mixture 13 exiting the cold plates 22 (or radiators 24) in a phase separator vessel 50 which serves as a substantially constant-head tank to maintain the liquid driving force to the cold plates 22. The portion of vapor separated from the 2-phase mixture 13 is labelled as 14a for illustration purpose. The vapor 14 is sent to the condenser 40, and the liquid 16 from the condenser 40 and the liquid separated 12a from the cold plate discharge are combined and return by to the cold plates 22. Though not shown on the figure, this arrangement may require separate return lines from each cold plate 22 (or radiator 24) to the head tank (i.e. the vessel 50), as the lower portions of a common return manifold may become flooded by un-evaporated fluid draining back, impeding the discharge from the lower cold plates 22 (or radiators 24)/return lines.

FIG. 3 illustrates a first exemplary system 210 for upgrading the waste heat via vapor recompression in accordance with some embodiments. Although it is based on the circulation configuration of FIG. 2, it is understood that it is also applicable to the circulation configuration of FIG. 1. The vapor 14 from the cold plates 22 (or radiators 24) is mechanically compressed using a compressor 60, thereby increasing its temperature and quality, using the principle of a heat pump. The heated higher pressure vapor 26 is sent to a condenser 40, rejecting the high-quality (or high temperature) heat 34 that can be used for useful purposes, such as process or space heating, driving the regenerator of an absorption or adsorption chiller system, or driving a turbo-generator or thermo-electric generator to produce electricity.

In some embodiments, the upgraded-quality (higher-temperature) waste heat 34 in the form of hot pressurized vapor discharged from the compressor 60 is used for process heating, by means a heat exchanger that serves as the condenser 40 for the evaporative working fluid.

In some embodiments, the upgraded-quality (higher-temperature) waste 34 heat in the form of hot pressurized vapor discharged from the compressor 60 is used for space heating, by means of air- or circulating water-cooled exchanger that serves as the condenser 40 for the evaporative working fluid.

In some embodiments, the upgraded-quality (higher-temperature) waste heat 34 in the form of hot pressurized vapor discharged from the compressor 60 is used for the production of chilled water or air, by means of an absorption- or adsorption-chiller (refrigeration) system, whereby the waste heat is used to regenerate the absorber fluid or adsorbent, with the regenerator serving as the condenser 40 for the evaporative working fluid.

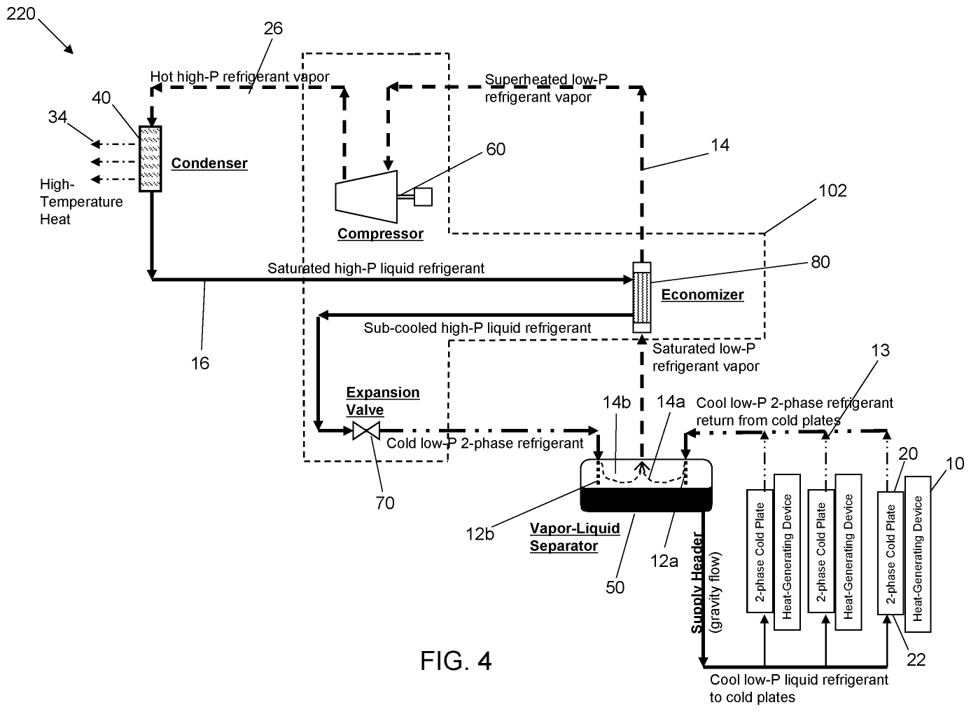

High-quality heat 34 recovered and upgraded in FIGS. 3-9 can be also used in any of these applications, and the uses of the high-quality heat 34 will not be repeated in FIGS. 4-9.

Referring to FIG. 3, the condensed working fluid 16 is let down through an expansion device 70 (valve or orifice), where it flash-expands and cools, producing a second 2-phase mixture 18 of the working fluid 12 at substantially the pressure of the fluid going to the cold plates 22. In FIG. 3, the compressor 60 and the expansion device 70 are shown in the dashed area 102 for illustration purpose. The flashed vapor 14b and liquid 12b are separated, with vapor 14b combined with the vapor 14a sent to the compressor, and the liquid 14b combined with the liquid 12b sent to the cold plates 22 (or radiators 24).

FIG. 4 illustrates a second exemplary system 220 for upgrading the waste heat via vapor recompression. Although it is based on the circulation configuration of FIG. 2, it is understood that it is also applicable to circulation configuration of FIG. 1. It uses the same operating principles and features of FIG. 3, but the efficiency is increased by using a heat exchanger (“economizer”) 80 to remove and further cool the condensed high-pressure working fluid 16, transferring the heat to and super-heating the vapor 14 sent to a compressor. The higher inlet temperature of the compressor 60 results in a correspondingly higher compressed vapor temperature and this higher-quality heat 34, from which more useful energy may be extracted.

In some embodiments, the vapor 14 entering the compressor is pre-heated and super-heated by a heat exchanger (“economizer”) 80 that transfers heat from and thereby sub-cools the liquid 16 exiting the condenser 40 for the evaporative working fluid, prior to its flash-expansion at the expansion device 70.

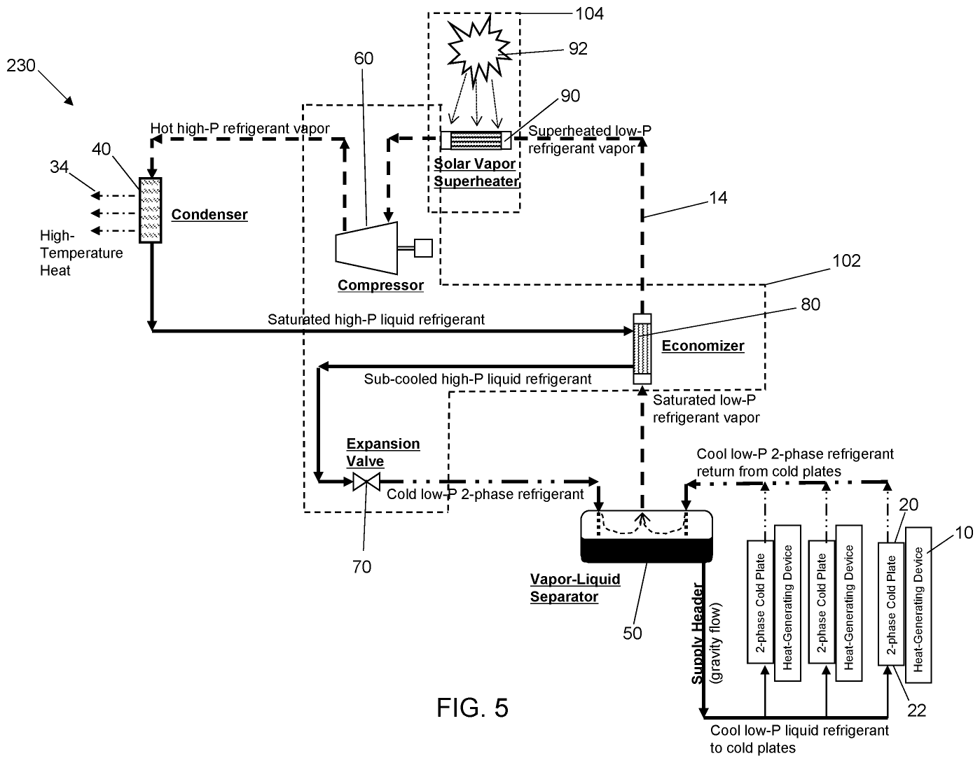

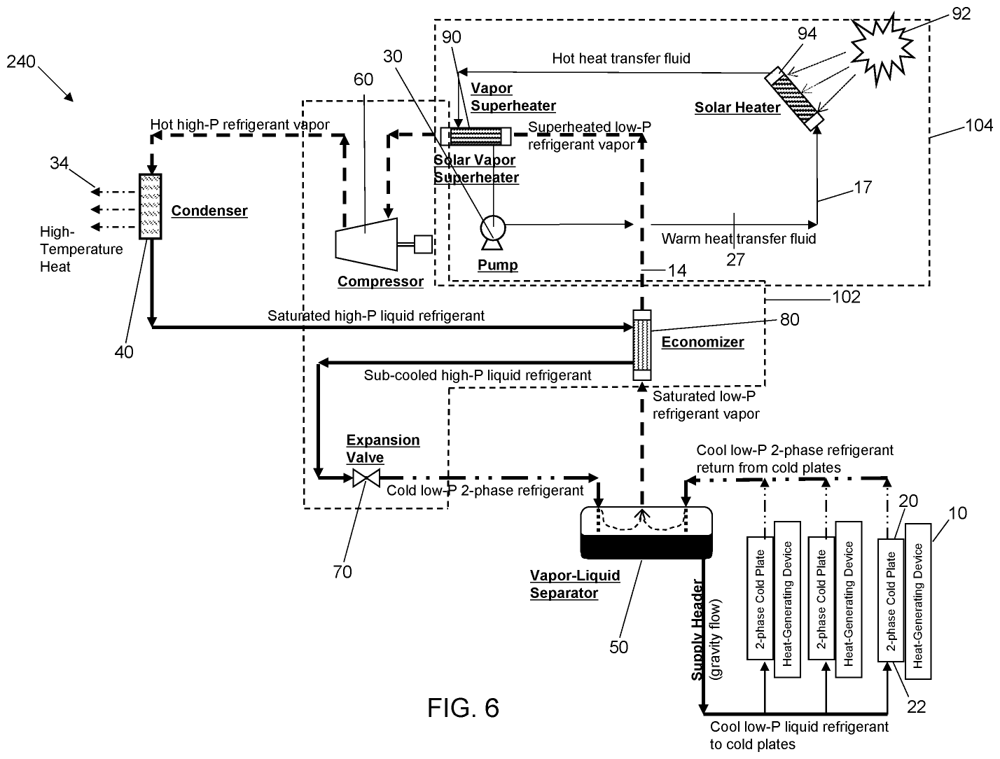

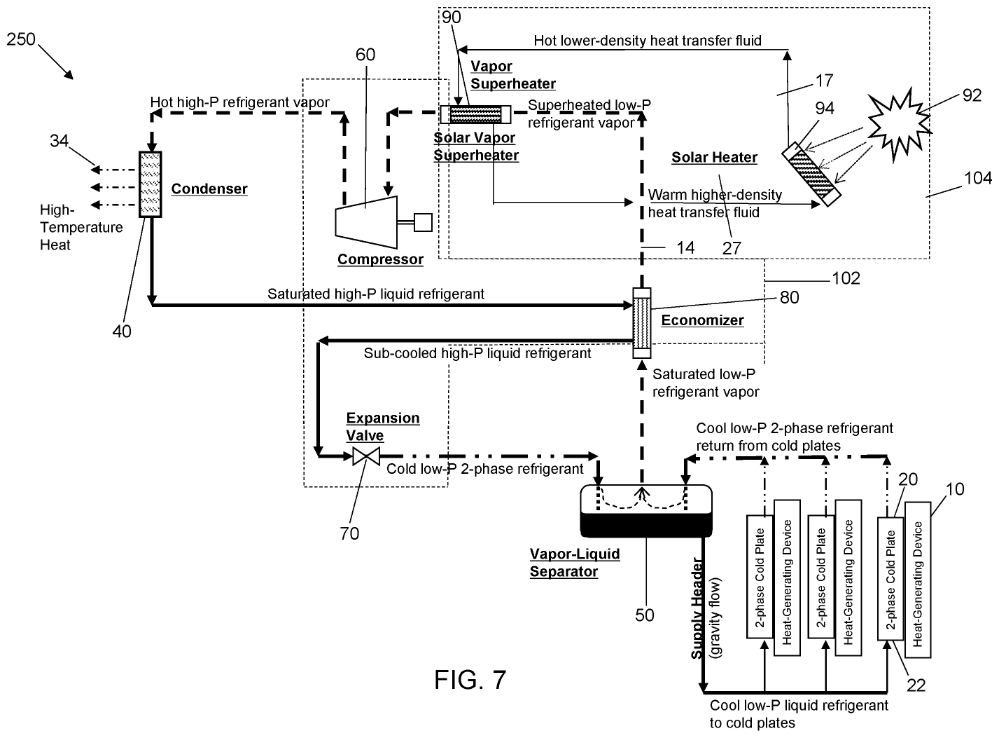

Referring to FIGS. 5-7, in some embodiments, the vapor 14 entering the compressor 60 is pre-heated and super-heated by a solar-powered heater 90. The solar powered heater may be heated directly by solar radiation 92 (FIG. 5), or indirectly by a secondary heat transfer fluid loop (FIGS. 6-7), which is heated by a separate solar heater 90. The circulation of the secondary heat transfer loop for the indirect solar heater may be driven by active means, such as a pump, or by passive means, such as natural circulation or the thermosiphon principle.

FIG. 5 illustrates a third exemplary system 230 for upgrading the waste heat via vapor recompression in accordance with some embodiments. Although it is based on the circulation configuration of FIG. 4, it is understood that it is also applicable to any circulation configuration illustrated in FIG. 1-3. It uses the same heat pump operating principles, but the efficiency is increased by using a direct solar-heater 90 to further super-heat the vapor 14 sent to compressor 60.

FIG. 6 illustrates a fourth exemplary system 240 for upgrading the waste heat via vapor recompression in accordance with some embodiments. FIG. 7 illustrates a fifth exemplary system 250 for upgrading the waste heat via vapor recompression in accordance with some embodiments. In FIGS. 6-7, the solar super-heating of the vapor 14 is used. Although the systems in FIGS. 6-7 are based on the circulation configuration of FIG. 4, it is understood that it is also applicable to any circulation configuration of FIGS. 1-3. Rather than directly superheating the vapor 14 to the compressor 60 using solar energy 92 as illustrated in FIG. 5, the vapor 14 is also heated by an intermediate circulation loop 27 of a secondary heat transfer fluid 17, which is heated externally by a separate solar-powered heater 94. The secondary (or intermediate) circulation loop 27 is illustrated in the dashed area 104. The secondary heat transfer fluid circulates from the solar-powered heater 94 to the vapor super-heater 90. A pump 30 may be used as illustrated in FIG. 6. This has the advantage of physically de-coupling the solar heater 94 from the primary vapor recompression system, allowing them to be physically separated and optimally placed.

FIG. 6 shows an actively (pumped) secondary circulation loop, whereas in FIG. 7, the secondary loop circulation is passive, using natural circulation driven by the temperature-sensitive differences in the fluid density (thermosiphon principle). No pump 30 is used in the intermediate loop 27 with secondary heat transfer fluid 17.

In some embodiments, the fluid used in the secondary heat transfer loop of a heated solar-powered vapor super-heater is heated by direct solar radiation via transparent sections of the solar heater. The secondary fluid that has high absorptivity of solar radiation, to maximize the exit temperature of the heated secondary fluid.

In some embodiments, the fluid 17 used in the secondary heat transfer loop 27 of a heated solar-powered vapor super-heater 90 is heated by direct solar radiation 92 via transparent sections of the solar heater 94. The secondary fluid 17 is a nano-fluid comprising dispersed nanoparticles which absorb and are warmed by the solar energy 92, and which conductively transfer the heat to the carrier fluid 17.

In some embodiments, the fluid 17 used in the secondary heat transfer loop 27 of a heated solar-powered vapor super-heater 90 is heated by direct solar radiation via transparent sections of the solar heater. The secondary fluid 17 is a nano-fluid comprising two or more distinct types of dispersed nanoparticles, each type of which is “tuned” to absorb a selected band of the solar spectrum, wherein the various nanoparticles which absorb and are warmed by their respective solar energy spectral bands, and respectively conductively transfer the heat to the carrier fluid 17.

In addition to cold plates 22, the heat absorption device 20 can also be indirect heat exchangers (e.g. rear-door heat exchangers [RDHX]) that cool (recirculated) air in enclosures from air-cooled electronics/data servers, via 2-phase cooling. The indirect heat exchanger act as the evaporators for the systems.

FIGS. 8-9 illustrated two exemplary systems 260, 270 including components for indirect cooling or hybrid cooling. The exemplary systems 260, 270 may also include other components illustrated in FIGS. 3-7.

FIG. 8 illustrates a sixth exemplary system 260 for upgrading the waste heat via vapor recompression while cooling electronic devices 10 and heat-generating equipment 28 with indirect 2-phase cooling in accordance with some embodiments. Referring to FIG. 8, indirect cooling and heat recovery are performed through air circulating between heat generating equipment 28 and an evaporator 24; the separated vapor from the indirect air-cooling evaporator 24 is sent to the vapor compressor 60 and heat upgrading system including condenser 40, analogously to those used in FIG. 3.

The heat-generating equipment 28 may be housed in an enclosure (e.g., a cabinet) 106 which may be substantially sealed or isolated from the external environment. The enclosure 106 and/or the heat generating equipment 28 contains one or more fans or blowers 25 that blow or suck cool air through conventional means for air-cooling the heat generating equipment 28. Examples of these means may include, but are not limited to, fins, jets, heat sinks, heat pipes, coils, and a combination thereof. The air is warmed by the absorbed heat and is exhausted from the heat generating equipment 28. The exhausted hot air is routed through and across one or more evaporative heat exchangers (evaporators or radiators) 24, and is cooled by evaporating working fluid (refrigerant) 12. With suitably sized evaporators 24 and air flow rates, the heated exhausted air is thereby cooled to a temperature within a few degrees of the working fluid 12, and is recirculated to the fans or blowers, to repeat the indirect cooling cycle.

The 2-phase mixture 13 leaving the evaporator 24 is sent to a phase separator 50. The vapor 14 is sent to a compressor, and the separated liquid 12a, along with the returning flashed liquid 12b from the condenser 40 and expansion valve/orifice portion 70 is returned to the evaporator (radiator) 24.

The vapor compressor 60 and energy recovery system operates substantially the same as the previously described direct cooling systems using cold plates 22 to cool the heat-generating devices 10 as shown in FIGS. 3-7. The other embodiments that may be used with direct cooling, as shown in the previous figures (FIGS. 3-7), such as the pumped circulation of the working fluid, vapor heat economizer 27, solar super-heaters 90, 94, and a secondary heating loop 27 may be applied to the indirect cooling variation of the present disclosure.

FIG. 9 illustrates a seventh exemplary system for upgrading the waste heat via vapor recompression while cooling electronic devices 10 and heat-generating equipment 28 with a hybrid (including both direct and indirect) 2-phase cooling in accordance with some embodiments.

Referring to FIG. 9, the exemplary system 270 includes a “hybrid” combination of indirect and direct 2-phase cooling and heat recovery via vapor recompression, by using both direct 2-phase-cooled cold plates and air cooling of the remaining equipment using a 2-phase evaporator (radiator) 24 to remove the heat from the cooling air. For the air-cooled equipment, air is circulated between the heat generating equipment 28 and an evaporator 24; the separated vapor from both the indirect air-cooling evaporator (or radiator) 24 and from the cold plates 22 is sent to the vapor compressor and heat upgrading system, analogously to those used in FIG. 3.

The indirectly air-cooled heat-generating equipment 28 and optionally the directly-cooled heat generating devices 10 are housed in an enclosure (e.g. a cabinet) 106, which may be substantially sealed or isolated from the external environment. The enclosure 106 and/or the heat generating equipment 28 contains one or more fans or blowers that blow or suck cool air through conventional means for air-cooling the heat generating equipment 28. Examples of these means include, but are not limited to fins, jets, heat sinks, heat pipes, coils, and a combination thereof. The air is warmed by the absorbed heat and is exhausted from the heat generating equipment 28. The exhausted hot air is routed through and across one or more evaporative heat exchangers (evaporators or radiators) 24, which is cooled by evaporating working fluid (refrigerant) 12. With suitably sized evaporators 24 and air flow rates, the heated exhausted air is thereby cooled to a temperature within a few degrees of the working fluid 12, and is recirculated to the fans or blowers 25, to repeat the indirect cooling cycle.

In parallel, working fluid 12 is sent to cold plates 22, which are in direct contact with the heat-generating devices 10. Heat is transferred from the devices 10 to the cold plates 22, inside of which the working fluid 12 absorbs the heat and partially evaporates.

As described above, the 2-phase mixture 13 leaving both the evaporator 24 and the cold plates 22 is sent to a phase separator 50; the vapor is sent to a compressor 60, and the separated liquid, along with the returning flashed liquid from the condenser 40 and expansion valve/orifice portion 70 is returned to the evaporator 24 and the cold plates 22.

The vapor compressor 60 and energy recovery system operates substantially the same as the previously described direct cooling systems using cold plates to cool the heat-generating devices 10 as shown in FIGS. 3-7. The other embodiments that may be used with direct cooling, as shown in the previous figures (FIGS. 3-7), such as the pumped circulation of the working fluid, vapor heat economizer 27, solar super-heaters 90, 94, and a secondary heating loop 27 may be applied to the indirect cooling variation such as the exemplary system 270.

The working liquids 12, 16, 18 and the vapor 14, 26 at different stages in this disclosure may have the same compositions, and the reference numerals 12, 14, 16, 18, and 26 may be used interchangeably.

Referring to FIG. 10, the present disclosure also provides an exemplary method 500 in accordance with some embodiments. The exemplary method 500 is also described in the exemplary systems above.

At step 502, an evaporable working liquid 12 is provided to a plurality of heat absorption devices 20 in proximity to or in direct or indirect thermal contact with a plurality electronic devices 10 and/or heating generating equipment 28. Each of the plurality of heat absorption devices 20 comprises at least one channel. The working liquid 12 becomes a first 2-phase mixture 13 having a first liquid portion 12a and a first vapor portion 14a (or labelled 14 in general) upon absorption of heat from the plurality of electronic devices 10 and/or heating generating equipment 28.

At step 504, the first vapor portion 14 are combined and compressed using at least one compressor 60 configured to form a compressed vapor 26 having an elevated pressure and an elevated temperature.

At step 506, the compressed vapor 26 is condensed to liquid 16 at the elevated pressure using at least one heat exchanger (or condenser) 40 configured so as to release and recover the heat.

At step 508, the liquid 16 is expanded at the elevated pressure using an expansion device 70 having a valve or an orifice to provide a second 2-phase mixture 18 at a reduced pressure comprising a second liquid portion 12b and a second vapor portion 14b.

At step 510, the first liquid portion 12a and the second liquid portion 12b in at least one vapor-liquid separator 50 are fed back to the plurality of heat absorption devices 20.

At step 510, the second vapor portion 14b is supplied back to the at least one compressor 60.

In some embodiments, the exemplary method 500 may include one or more steps of using the components described above for direct cooling, as shown in FIGS. 3-7, or for indirect cooling or hybrid cooling as shown in FIGS. 8-9. Examples of the one or more further steps include the pumped circulation of the working fluid, using vapor heat economizer 27, using solar super-heaters 90, 94, and using a secondary heating loop 27.

### Examples

1. Electronics cooling with waste heat upgraded for process or space heating

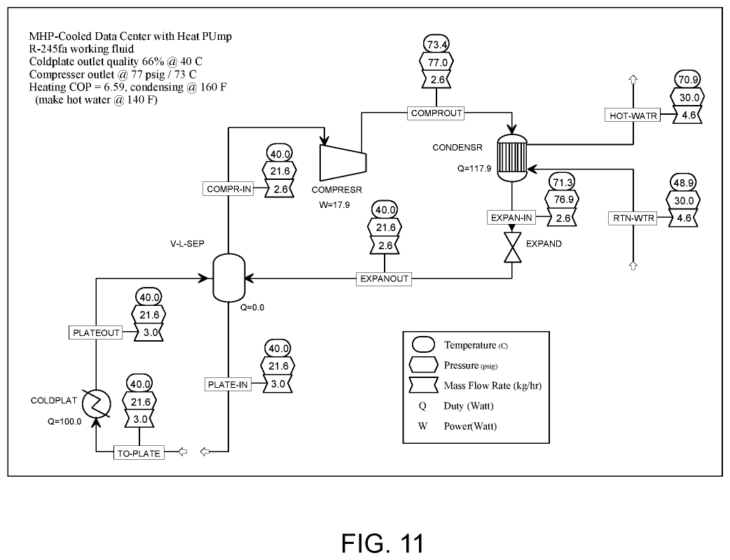

FIG. 11 is a flow diagram generated by ASPEN PLUS® simulation/modeling software showing electronics cooling with waste heat upgraded for process or space heating in some embodiments.

2. Electronics cooling with upgraded waste heat driving absorption chiller

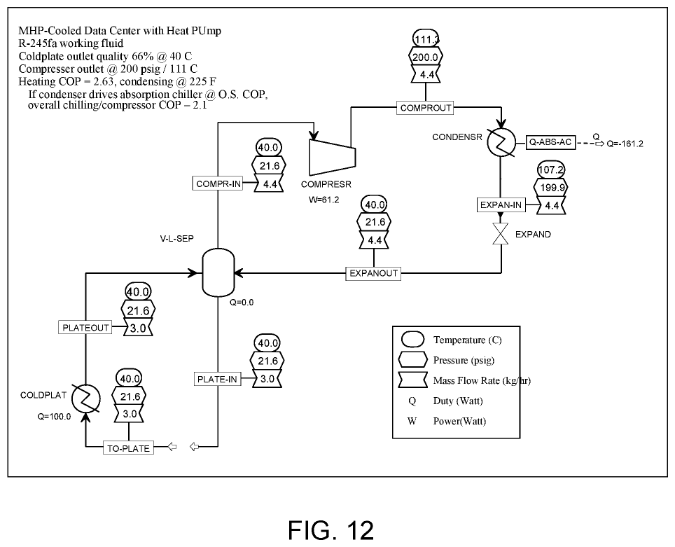

FIG. 12 is another flow diagram generated by ASPEN PLUS® simulation/modeling software showing electronics cooling with waste heat upgraded for driving absorption chiller in some embodiments.

3. Data Center Energy Recovery

System-level modeling was performed on a data center system using the Villanova Thermodynamic Analysis of Systems (VTAS), a modeling software developed by Villanova University, for comparison with other cooling approaches. The data center testbed used here contains 2 rows of 10 racks each, where each rack contains 1.2 kW of power consumption. The metric used here is the extended energy reuse factor (EERE) parameter, which is defined as (net energy captured and reused in the facility)/(data center IT load). A lower EERE parameter indicates a more efficient system. When no waste heat recovery is used, then the EERE equals the power usage effectiveness (PUE), which is a standard metric for data center efficiency and is defined as (data center total load)/(data center IT load). Different systems are examined below:

(a) A system containing a single computer room air handler (CRAH), chiller, cooling tower, and the two-phase absorption refrigeration system, where all heat is captured at the servers, and the resultant heat pump chilling and condenser-side heating are utilized elsewhere in the facility: EERE=−0.44.

(b) A system containing a single CRAH, chiller, cooling tower, and general two-phase heat recovery heat pump, where the condenser-side heating is utilized elsewhere in the facility: EERE=0.05.

(c) A system containing a single CRAH, chiller, and cooling tower: EERE=1.34

(d) A system containing a single computer room air conditioning (CRAC) unit: EERE=1.34.

One can clearly see from examples (a) and (b), using the subject invention for energy recovery, vs. the conventional approach of counter-examples (c) and (d), that data centers using the heat upgrading and energy recovery of the subject invention can potentially provide a net energy benefit to other locations within the facility, provided that the additional heat and cooling generated from the process is strategically implemented (e.g., facility hot water preheating, chilled water precooling, etc.). In fact, the data center in this case acts as an energy provider to the remainder of the facility, reducing the inlet electrical energy from the grid to the non-data center portions of the facility.

Although the subject matter has been described in terms of exemplary embodiments, it is not limited thereto. Rather, the appended claims should be construed broadly, to include other variants and embodiments, which may be made by those skilled in the art.

What is claimed is:

1. A system comprising:
a plurality of heat absorption devices in thermal communication with a plurality electronic devices, each of the plurality of heat absorption devices comprising at least one channel configured to receive and circulate an evaporable working liquid, the working liquid configured to become a first 2-phase mixture having a first liquid portion and a first vapor portion upon absorption of heat from the plurality of electronic devices;
at least one compressor configured to combine the first vapor portion from the plurality of heat absorption devices and compress the first vapor portion to form a compressed vapor having an elevated pressure and an elevated temperature;
at least one heat exchanger configured to condense the compressed vapor to liquid at the elevated pressure so as to release and recover the heat;
an expansion device configured to expand the liquid at the elevated pressure to provide a second 2-phase mixture at a reduced pressure comprising a second liquid portion and a second vapor portion; and
at least one vapor-liquid separator configured to feed the first liquid portion and the second liquid portion back to the plurality of heat absorption devices, and to supply the second vapor portion back to the at least one compressor,
wherein the plurality of heat absorption devices, the at least one compressor, and the at least one heat exchanger, the expansion device, and the at least one vapor-liquid separator are fluidly coupled together in a flowing direction of the working liquid and the first and the second 2-phase mixtures.

2. The system of claim 1, wherein the system is in a closed loop and the working fluid is in gravity-driven circulation.

3. The system of claim 1, wherein each of the plurality of heat absorption devices is selected from the group consisting of a cold plate, a radiator, and a combination thereof.

4. The system of claim 1, wherein the plurality of heat absorption devices include cold plates and radiators.

5. The system of claim 1, further comprising an internal heat exchanger configured to further heat the first vapor portion from the plurality of heat absorption devices, and further cool the liquid at the elevated pressure from the at least one heat exchanger before the liquid is supplied to the expansion device.

6. The system of claim 1, further comprising a solar powered heater configured to further heat the first vapor portion before the first vapor is provided to at least one compressor.

7. The system of claim 6, wherein the solar powered heater is directly heated by solar radiation, or comprises a secondary heat fluid loop comprising a secondary heat transfer fluid.

8. The system of claim 7, wherein the secondary heat transfer fluid comprises a nano-fluid including dispersed nanoparticles.

9. The system of claim 1, further comprising a sub-system configured to utilize the heat recovered from the at least one heat exchanger.

10. A method comprising:
providing an evaporable working liquid to a plurality of heat absorption devices in thermal communication with a plurality electronic devices, each of the plurality of heat absorption devices comprising at least one channel, the working liquid becoming a first 2-phase mixture having a first liquid portion and a first vapor portion upon absorption of heat from the plurality of electronic devices;
combining and compressing the first vapor portion from the plurality of heat absorption devices using at least one compressor configured to form a compressed vapor having an elevated pressure and an elevated temperature;
condensing the compressed vapor to liquid at the elevated pressure using at least one heat exchanger configured so as to release and recover the heat;
expanding the liquid at the elevated pressure using an expansion device to provide a second 2-phase mixture at a reduced pressure comprising a second liquid portion and a second vapor portion;
feeding the first liquid portion and the second liquid portion back to the plurality of heat absorption devices in at least one vapor-liquid separator; and
supplying the second vapor portion back to the at least one compressor.

11. The method of claim 10, wherein the system is in a closed loop and the working fluid is in gravity-driven circulation.

12. The method of claim 10, further comprising using an internal heat exchanger to further heat the first vapor portion, and further cool the liquid at the elevated pressure from the at least one heat exchange before the liquid is supplied to the expansion device.

13. The method of claim 10, further comprising further heating the first vapor portion using a solar powered heater before the first vapor is provided to at least one compressor.

14. The method of claim 13, wherein the solar powered heater is directly heated by solar radiation, or comprises a secondary heat fluid loop comprising a secondary heat transfer fluid.

15. The method of claim 10, further comprising utilizing the heat recovered from the at least one heat exchanger.

16. The method of claim 15, wherein the heat recovered is utilized for any of process heating, space heating, and driving the regenerator for an absorption or adsorption chiller, mechanical or thermoelectric generator.

17. The method of claim 10, wherein the evaporable working fluid is a refrigerant.

18. The method of claim 10, wherein the plurality of electronic devices are components in a data center.

19. The method of claim 17, wherein the refrigerant is any or a mixture of the following: R-134a, R-245fa, R-1233zd, R-1234yf or R-1234ze.
